(19) United States
(12) Patent Application Publication
(10) Pub. No.: US 2024/0368045 A1
(43) Pub. Date: Nov. 7, 2024

(54) SILICON BOND COAT WITH AMORPHOUS STRUCTURE AND METHODS OF ITS FORMATION

(71) Applicant: General Electric Company, Schenectady, NY (US)

(72) Inventors: Glen Harold Kirby, Liberty Township, OH (US); Justin Michael Nagy, Newport, KY (US); John Tam Nguyen, Cincinnati, OH (US); Jeffrey Allen Bross, Liberty Township, OH (US); Brian Harvey Pilsner, Mason, OH (US); Robert Martin Fecke, Franklin, OH (US)

(21) Appl. No.: 18/776,465

(22) Filed: Jul. 18, 2024

Related U.S. Application Data
(62) Division of application No. 16/050,310, filed on Jul. 31, 2018.

(51) Int. Cl. C04B 41/89; C04B 35/16; C04B 35/462; C04B 35/584

(52) U.S. Cl. CPC C04B 41/89; C04B 35/16; C04B 35/462; C04B 35/584; C04B 2235/3418

(57) ABSTRACT

Methods of forming a coated component are provided. The coated component includes a substrate having a surface; a silicon-based bond coating on the surface of the substrate; and a barrier coating on the silicon-based bond coating. The silicon-based bond coating comprises amorphous silicon phase having grains of crystalline silicon (e.g., having an average size of about 0.03 μm to about 3 μm) distributed therein. The amorphous silicon phase may be formed of pure silicon metal, or may be formed from silicon metal with boron, oxygen, and/or nitrogen dispersed therein.

### PRIORITY INFORMATION

The present application claims priority to U.S. application Ser. No. 16/050,310 filed on Jul. 31, 2018, the disclosure of which is incorporated by reference herein in its entirety for all purposes.

### FIELD

The present invention generally relates to bond coatings for use with environmental barrier coatings on ceramic components, along with methods of their formation and use.

### BACKGROUND

Higher operating temperatures for gas turbine engines are continuously being sought in order to improve their efficiency. However, as operating temperatures increase, the high temperature durability of the components of the engine must correspondingly increase. Significant advances in high temperature capabilities have been achieved through the formulation of iron, nickel, and cobalt-based superalloys. Still, with many hot gas path components constructed from super alloys, thermal barrier coatings (TBCs) can be utilized to insulate the components and can sustain an appreciable temperature difference between the load-bearing alloys and the coating surface, thus limiting the thermal exposure of the structural component.

While superalloys have found wide use for components used throughout gas turbine engines, and especially in the higher temperature sections, alternative lighter-weight substrate materials have been proposed, such as ceramic matrix composite (CMC) materials. CMC and monolithic ceramic components can be coated with environmental barrier coatings (EBCs) to protect them from the harsh environment of high temperature engine sections. EBCs can provide a dense, hermetic seal against the corrosive gases in the hot combustion environment.

Silicon carbide and silicon nitride ceramics undergo oxidation in dry, high temperature environments. This oxidation produces a passive, silicon oxide scale on the surface of the material. In moist, high temperature environments containing water vapor, such as a turbine engine, both oxidation and recession occurs due to the formation of a passive silicon oxide scale and subsequent conversion of the silicon oxide to gaseous silicon hydroxide. To prevent recession in moist, high temperature environments, environmental barrier coatings (EBC's) are deposited onto silicon carbide and silicon nitride materials.

Currently, EBC materials are made out of rare earth silicate compounds. These materials seal out water vapor, preventing it from reaching the silicon oxide scale on the silicon carbide or silicon nitride surface, thereby preventing recession. Such materials cannot prevent oxygen penetration, however, which results in oxidation of the underlying substrate. Oxidation of the substrate yields a passive silicon oxide scale, along with the release of carbonaceous or nitrous oxide gas. The carbonaceous (i.e., CO, CO₂) or nitrous (i.e., NO, NO₂, etc.) oxide gases cannot escape out through the dense EBC and thus, blisters form. The use of a silicon bond coating has been the solution to this blistering problem to date. The silicon bond coating provides a layer that oxidizes (forming a passive silicon oxide layer beneath the EBC) without liberating a gaseous by-product.

If the silicon bond coat contains linear defects (e.g. cracks) either via the manufacturing process or during service, particularly linear defects that span the entire layer thickness, the silicon bond coat may fail to provide the oxidation protection at that location. Such a breach may lead to local oxidation of the substrate and liberation of gas that can blister and rupture the overlying EBC or in worst case, lead to delamination of large sections of EBC. In either case, the missing EBC allows for high temperature steam to penetrate and corrosively attack the underlying substrate. As-manufactured silicon bond coats via air plasma spray (APS) tend to contain microstructural features that can result in low cohesive strength of the bond coat. Furthermore, silicon bond coats manufactured via chemical vapor deposition (CVD) can have large grain size in EBC systems. Since the overlying rare earth silicate layers are processed at temperatures higher than CVD silicon processing temperatures, grain growth occurs and can result in grains that comprise the entire thickness of the bond coat. According to the Hall-Petch relationship, it is known that enormous grains in a material produce a knock-down in mechanical capability relative to the same material with fine grains.

As such, there is a need for improved bond coats with CMC substrates for use with EBCs.

### BRIEF DESCRIPTION

Aspects and advantages will be set forth in part in the following description, or may be obvious from the description, or may be learned through practice of the invention.

A coated component is generally provided, along with methods of its formation and use. In one embodiment, the coated component includes a substrate having a surface; a silicon-based bond coating on the surface of the substrate; and a barrier coating on the silicon-based bond coating. The silicon-based bond coating generally comprises amorphous silicon phase having grains of crystalline silicon (e.g., having an average size of about 0.03 μm to about 3 μm) distributed therein. For example, the amorphous silicon phase may be formed of pure silicon metal, or may be formed from silicon metal with boron, oxygen, and/or nitrogen dispersed therein.

In particular embodiments, the grains of crystalline silicon form about 0.1% to about 99% by volume of the silicon-based bond coating (e.g., about 1% to about 65% by volume of the silicon-based bond coating, such as about 1% to about 40% by volume of the silicon-based bond coating).

The method of forming a coated component may include forming a silicon-based bond coating on a surface of a substrate and forming a barrier coating on the silicon-based bond coating. The silicon-based bond coating comprises amorphous silicon phase having grains of crystalline silicon distributed therein. For example, forming the silicon-based bond coating on the surface of the substrate is achieved by: chemical vapor depositing a silicon-containing precursor at a deposition temperature that prevents crystallization of the silicon material during the deposition of the silicon-based bond coating and heat treating the silicon-based bond coating at a treatment temperature that is higher than the deposition temperature so as to form the grains of crystalline silicon distributed within the amorphous silicon phase.

In particular embodiments, the deposition temperature is about 300° C. to about 700° C., such as about 700° C. to about 1000° C., and/or the treatment temperature is about 1000° C. to about 1400° C.

A turbine component is also generally provided. For example, the turbine component may include a substrate comprising a ceramic matrix composite, a silicon-based bond coating on the surface of the substrate, and a barrier coating on the silicon-based bond coating. The silicon-based bond coating comprises amorphous silicon phase having grains of crystalline silicon distributed therein.

These and other features, aspects and advantages will become better understood with reference to the following description and appended claims. The accompanying drawings, which are incorporated in and constitute a part of this specification, illustrate embodiments of the invention and, together with the description, serve to explain certain principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended Figs., in which:

FIG. 1 is a cross-sectional side view of an exemplary coated component including a silicon-based bond coating;

FIG. 2 is another cross-sectional side view of an exemplary coated component including a silicon-based bond coating with a thermally grown oxide layer thereon;

FIG. 3 is a cross-sectional side view of an exemplary silicon-based bond coating having grains of crystalline silicon dispersed within an amorphous silicon phase;

FIG. 4 is a cross-sectional side view of another exemplary silicon-based bond coating having grains of crystalline silicon dispersed within an amorphous silicon phase;

FIG. 5 is a schematic cross-sectional view of an exemplary gas turbine engine according to various embodiments of the present subject matter; and

FIG. 6 is a diagram of an exemplary method of forming a silicon-based bond coating with grains of crystalline silicon dispersed within an amorphous silicon phase.

Repeat use of reference characters in the present specification and drawings is intended to represent the same or analogous features or elements of the present invention.

### DETAILED DESCRIPTION OF PARTICULAR EMBODIMENTS

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the terms “first”, “second”, and “third” may be used interchangeably to distinguish one component from another and are not intended to signify location or importance of the individual components.

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth. As used herein, “Ln” refers to a rare earth element or a mixture of rare earth elements. More specifically, the “Ln” refers to the rare earth elements of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), or mixtures thereof.

As used herein, the term “substantially free” means no more than an insignificant trace amount present and encompasses completely free (e.g., 0 molar % up to 0.01 molar %). In this disclosure the term “about” is used to mean approximate or nearly, as is reasonably understood in the art.

In the present disclosure, when a layer is being described as “on” or “over” another layer or substrate, it is to be understood that the layers can either be directly contacting each other or have another layer or feature between the layers, unless expressly stated to the contrary. Thus, these terms are simply describing the relative position of the layers to each other and do not necessarily mean “on top of” since the relative position above or below depends upon the orientation of the device to the viewer.

A coated component is provided that includes a silicon-based bond coating positioned between the surface of the substrate and a barrier coating (e.g., EBC) thereon, along with methods of its formation and use. The silicon-based bond coating generally has a microstructure that is largely amorphous silicon material (e.g., amorphous silicon) with small crystalline grains of silicon dispersed within the amorphous silicon material. It has been found that such a silicon-based bond coating is stronger relative to a bond coating having a crystalline silicon microstructure with very large grains. As such, the silicon-based bond coating may bond the substrate to the barrier coating (e.g., EBC) thereon, as well as gettering of oxygen without releasing gas to prevent oxidation of the underlying substrate that would otherwise result in a gaseous by-product.

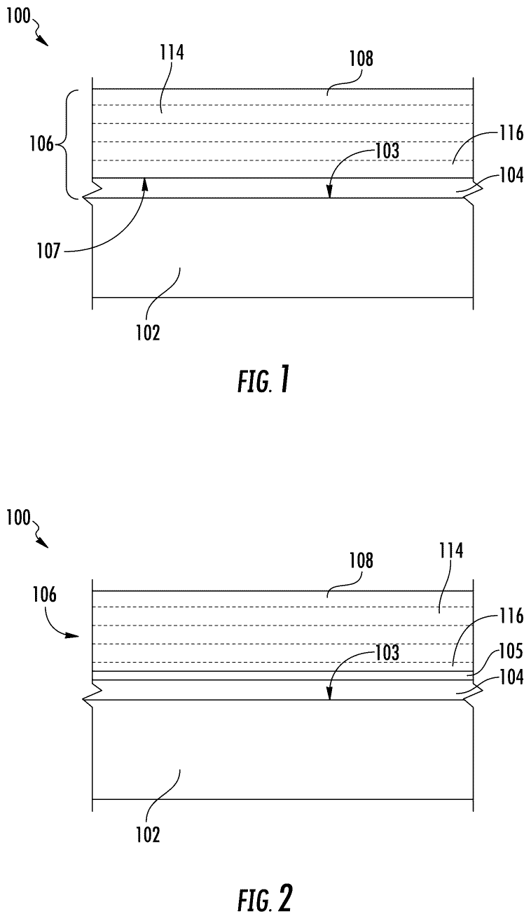

Referring to FIG. 1, an exemplary coated component 100 is shown formed from a substrate 102 having a surface 103 with a coating system 106 thereon. Generally, the coating system 106 includes a silicon-based bond coating 104 on the surface 103 of the substrate, and an EBC 108 on the silicon-based bond coating 104. In the embodiment shown, the silicon-based bond coating 104 is directly on the surface 103 without any layer therebetween. However, in other embodiments, one or more layers can be positioned between the silicon-based bond coating 104 and the surface 103. FIG. 2 shows a thermally grown oxide (“TGO”) layer 105, which may form on the surface of the silicon-based bond coating 104, such as a layer of silicon oxide (sometimes referred to as “silicon oxide scale” or “silica scale”), during exposure to oxygen (e.g., during manufacturing and/or use) of the component 100.

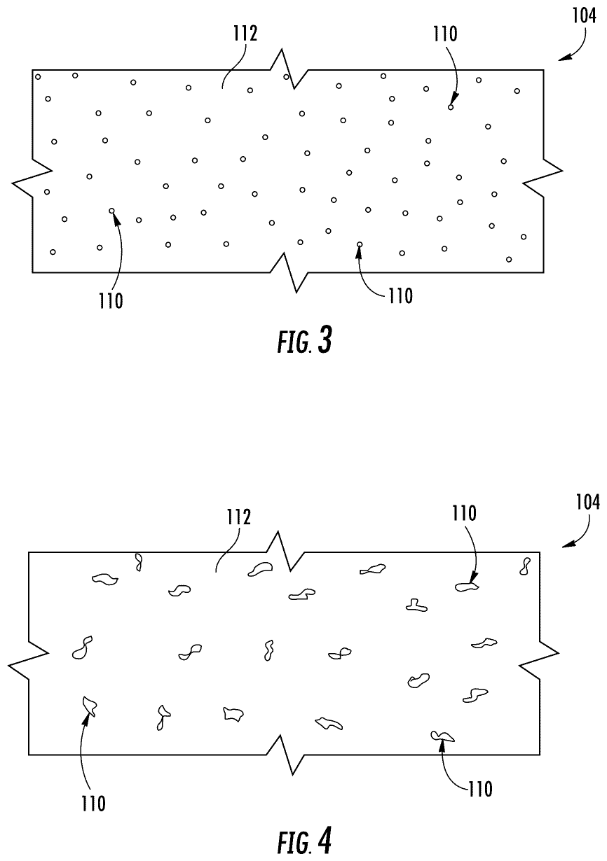

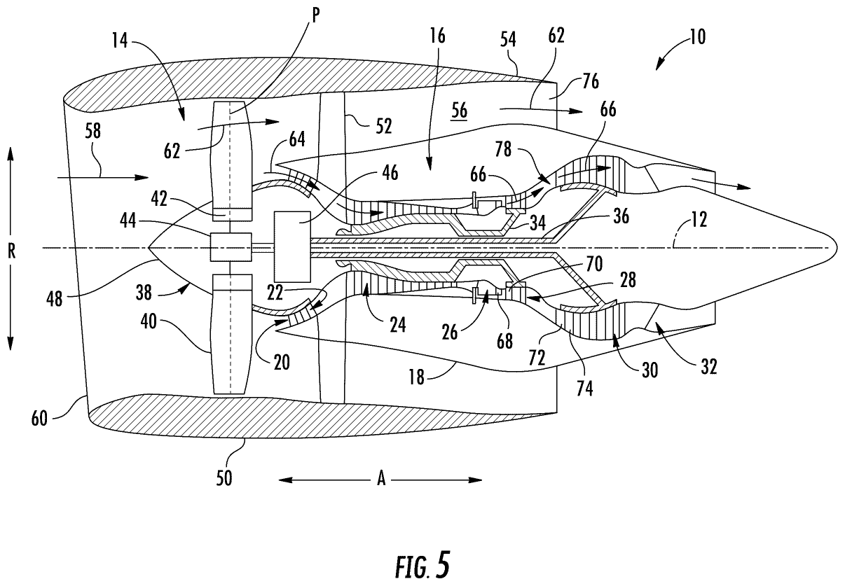

FIGS. 3 and 4 show close-up cross-sections of exemplary silicon-based bond coatings 104, such as for use in the exemplary coated component 100 of FIG. 1 or 2, having an amorphous silicon phase 112 having discrete grains 110 of crystalline silicon dispersed therein. Referring to FIG. 3, the discrete grains 110 of crystalline silicon have substantially round shapes, while the discrete grains 110 of crystalline silicon of FIG. 4 have an irregular shape. In particular embodiments, the grains 110 of crystalline silicon may have an average size that is about 0.03 μm to about 3 μm.

In both embodiments of FIGS. 3 and 4, the amorphous silicon phase 112 is a continuous phase, and the grains 110 of crystalline silicon form a plurality of discrete particulate phases within the amorphous silicon phase 112. In the embodiments shown, the amorphous silicon phase 112 forms a 3-dimensional network that spans the thickness of the silicon-based bond coating 104 and is bonded to the surface 103 of the substrate 102 and to an inner surface 107 of the barrier coating 106. Generally, the silicon-based bond coating 104 is relatively thin. In particular embodiments, the silicon-based bond coating 104 may have a thickness that is about 25 micrometers (μm) to about 275 μm, such as about 25 μm to about 150 μm (e.g., about 25 μm to about 100).

The amorphous silicon phase 112 includes silicon metal, in the form of pure silicon or silicon with a small amount of boron, oxygen, and/or nitrogen dispersed within the silicon. For example, in certain embodiments, the amorphous silicon phase 112 comprises silicon metal in an amount of about 60% to 99.9% by volume (e.g., about 75% to 99% by volume).

The grains 110 of crystalline silicon form, in one embodiment, about 0.1% to about 99% by volume (e.g., about 1% to about 65% by volume, such as about 1% to about 40% by volume) of the silicon-based bond coating 104.

No matter the size and/or shape of the discrete grains 110 of crystalline silicon, the discrete grains 110 of crystalline silicon are distributed substantially uniformly throughout the amorphous silicon phase 112 in the embodiments of FIGS. 3 and 4.

In one particular embodiment, the silicon-based bond coating 104 is formed using a chemical vapor deposition (CVD) process using a silicon-containing precursor (e.g., those from the silane family such as SiH₄ and the higher silanes, SiₙH₂ₙ₊₂ (with n being an integer from 2-12, such as n=2 to form Si₄H₁₀). Also included are precursors from the chlorosilane family such as SiCl₄, SiHCl₃, SiH₂Cl₂, SiH₃Cl and the higher chlorosilanes thereof) at a relatively low deposition temperature (e.g., about 300° C. to about 700° C.) and relatively broad deposition pressure conditions (e.g., about 9 to about 760 Torr) depending on the precursor used. Without being bound by any particular theory, it is believed that these relatively low deposition temperatures (e.g., less than 700° C. and as low as 300 C) may be used to achieve amorphous silicon bond coats; however, deposition temperatures of above 700° C. (e.g., about 700° C. to about 1000° C.) are not excluded given optimization of other parameters including precursor type and pressure.

Without wishing to be bound by any particular theory, it is believed that these temperature and pressure conditions prevent significant crystallization of the silicon-based bond coating 104 during its formation, especially when utilizing the higher silanes and chlorosilanes. The amorphous versus crystalline nature of the CVD silicon bond coat is less dependent on the precursor flow rate. This may range from about 0.1 grams per minute (g/m) to about 2 g/m in a typical CVD process and is a balance between deposition rate and coating uniformity on the geometry of substrate that is desired to coat.

After deposition, the silicon-based bond coating 104 is heat treated to form the small grains 110 of crystalline silicon dispersed within the amorphous silicon phase 112. For example, the silicon-based bond coating 104 may be subjected to a treatment temperature that is higher than the deposition temperature, such as about 1000° C. to about 1400° C. (e.g., about 1200° C. to about 1350° C.).

Referring again to FIGS. 1 and 2, the substrate 102 may be formed from a ceramic matrix composite (“CMC”) material, such as a silicon based, non-oxide ceramic matrix composite. As used herein, “CMC” refers to a silicon-containing, or oxide-oxide, matrix and reinforcing material. As used herein, “monolithic ceramics” refers to materials without fiber reinforcement (e.g., having the matrix material only). Herein, CMCs and monolithic ceramics are collectively referred to as “ceramics.”

Some examples of CMCs acceptable for use herein can include, but are not limited to, materials having a matrix and reinforcing fibers comprising non-oxide silicon-based materials such as silicon carbide, silicon nitride, silicon oxycarbides, silicon oxynitrides, and mixtures thereof. Examples include, but are not limited to, CMCs with silicon carbide matrix and silicon carbide fiber; silicon nitride matrix and silicon carbide fiber; and silicon carbide/silicon nitride matrix mixture and silicon carbide fiber. Furthermore, CMCs can have a matrix and reinforcing fibers comprised of oxide ceramics. Specifically, the oxide-oxide CMCs may be comprised of a matrix and reinforcing fibers comprising oxide-based materials such as aluminum oxide (Al₂O₃), silicon dioxide (SiO₂), aluminosilicates, and mixtures thereof. Aluminosilicates can include crystalline materials such as mullite (3Al₂O₃ 2SiO₂), as well as glassy aluminosilicates.

The resulting amorphous silicon bond coat has a cohesive strength larger than that of silicon processed via air plasma spray, i.e., greater than 6,000 psi. Furthermore, the crystalline silicon grains within amorphous silicon matrix may serve to enhance resistance to crack growth through the bond coat via a crack deflection mechanism.

As stated above, the silicon-based bond coating 104 may be used in conjunction with a barrier coating 108 (e.g., EBC) to form a coated component 100 with an increased operating temperature compared to that using only a silicon bond coating. The barrier coating 108 may include any combination of one or more layers formed from materials selected from typical EBC or thermal barrier coating (“TBC”) layer chemistries, including but not limited to rare earth silicates (e.g., mono-silicates and di-silicates), aluminosilicates (e.g., mullite, barium strontium aluminosilicate (BSAS), rare earth aluminosilicates, etc.), hafnia, zirconia, stabilized hafnia, stabilized zirconia, rare earth hafnates, rare earth zirconates, rare earth gallium oxide, etc.

The barrier coating 108 may be formed from a plurality of individual layers 114. In the embodiments shown, barrier coating 108 includes a hermetic layer 116 positioned in directly on the silicon-based bond coating 104 so as to encase the amorphous silicon phase 112 in case of partial softening and/or melting at higher temperatures. However, in other embodiments, the hermetic layer 116 may be positioned elsewhere within the EBC 108.

The coated component 100 is particularly suitable for use as a component found in high temperature environments, such as those present in gas turbine engines, for example, combustor components, turbine blades, shrouds, nozzles, heat shields, and vanes. In particular, the turbine component can be a CMC component positioned within a hot gas flow path of the gas turbine such that the coating system 106 forms an environmental barrier for the underlying substrate 102 to protect the component 100 within the gas turbine when exposed to the hot gas flow path.

FIG. 5 is a schematic cross-sectional view of a gas turbine engine in accordance with an exemplary embodiment of the present disclosure. More particularly, for the embodiment of FIG. 5, the gas turbine engine is a high-bypass turbofan jet engine 10, referred to herein as “turbofan engine 10.” As shown in FIG. 5, the turbofan engine 10 defines an axial direction A (extending parallel to a longitudinal centerline 12 provided for reference) and a radial direction R. In general, the turbofan 10 includes a fan section 14 and a core turbine engine 16 disposed downstream from the fan section 14. Although described below with reference to a turbofan engine 10, the present disclosure is applicable to turbomachinery in general, including turbojet, turboprop and turboshaft gas turbine engines, including industrial and marine gas turbine engines and auxiliary power units.

The exemplary core turbine engine 16 depicted generally includes a substantially tubular outer casing 18 that defines an annular inlet 20. The outer casing 18 encases, in serial flow relationship, a compressor section including a booster or low pressure (LP) compressor 22 and a high pressure (HP) compressor 24; a combustion section 26; a turbine section including a high pressure (HP) turbine 28 and a low pressure (LP) turbine 30; and a jet exhaust nozzle section 32. A high pressure (HP) shaft or spool 34 drivingly connects the HP turbine 28 to the HP compressor 24. A low pressure (LP) shaft or spool 36 drivingly connects the LP turbine 30 to the LP compressor 22.

For the embodiment depicted, the fan section 14 includes a variable pitch fan 38 having a plurality of fan blades 40 coupled to a disk 42 in a spaced apart manner. As depicted, the fan blades 40 extend outwardly from disk 42 generally along the radial direction R. Each fan blade 40 is rotatable relative to the disk 42 about a pitch axis P by virtue of the fan blades 40 being operatively coupled to a suitable actuation member 44 configured to collectively vary the pitch of the fan blades 40 in unison. The fan blades 40, disk 42, and actuation member 44 are together rotatable about the longitudinal axis 12 by LP shaft 36 across an optional power gear box 46. The power gear box 46 includes a plurality of gears for stepping down the rotational speed of the LP shaft 36 to a more efficient rotational fan speed.

Referring still to the exemplary embodiment of FIG. 5, the disk 42 is covered by rotatable front nacelle 48 aerodynamically contoured to promote an airflow through the plurality of fan blades 40. Additionally, the exemplary fan section 14 includes an annular fan casing or outer nacelle 50 that circumferentially surrounds the fan 38 and/or at least a portion of the core turbine engine 16. It should be appreciated that the nacelle 50 may be configured to be supported relative to the core turbine engine 16 by a plurality of circumferentially-spaced outlet guide vanes 52. Moreover, a downstream section 54 of the nacelle 50 may extend over an outer portion of the core turbine engine 16 so as to define a bypass airflow passage 56 therebetween.

During operation of the turbofan engine 10, a volume of air 58 enters the turbofan 10 through an associated inlet 60 of the nacelle 50 and/or fan section 14. As the volume of air 58 passes across the fan blades 40, a first portion of the air 58 as indicated by arrows 62 is directed or routed into the bypass airflow passage 56 and a second portion of the air 58 as indicated by arrow 64 is directed or routed into the LP compressor 22. The ratio between the first portion of air 62 and the second portion of air 64 is commonly known as a bypass ratio. The pressure of the second portion of air 64 is then increased as it is routed through the high pressure (HP) compressor 24 and into the combustion section 26, where it is mixed with fuel and burned to provide combustion gases 66.

The combustion gases 66 are routed through the HP turbine 28 where a portion of thermal and/or kinetic energy from the combustion gases 66 is extracted via sequential stages of HP turbine stator vanes 68 that are coupled to the outer casing 18 and HP turbine rotor blades 70 that are coupled to the HP shaft or spool 34, thus causing the HP shaft or spool 34 to rotate, thereby supporting operation of the HP compressor 24. The combustion gases 66 are then routed through the LP turbine 30 where a second portion of thermal and kinetic energy is extracted from the combustion gases 66 via sequential stages of LP turbine stator vanes 72 that are coupled to the outer casing 18 and LP turbine rotor blades 74 that are coupled to the LP shaft or spool 36, thus causing the LP shaft or spool 36 to rotate, thereby supporting operation of the LP compressor 22 and/or rotation of the fan 38.

The combustion gases 66 are subsequently routed through the jet exhaust nozzle section 32 of the core turbine engine 16 to provide propulsive thrust. Simultaneously, the pressure of the first portion of air 62 is substantially increased as the first portion of air 62 is routed through the bypass airflow passage 56 before it is exhausted from a fan nozzle exhaust section 76 of the turbofan 10, also providing propulsive thrust. The HP turbine 28, the LP turbine 30, and the jet exhaust nozzle section 32 at least partially define a hot gas path 78 for routing the combustion gases 66 through the core turbine engine 16.

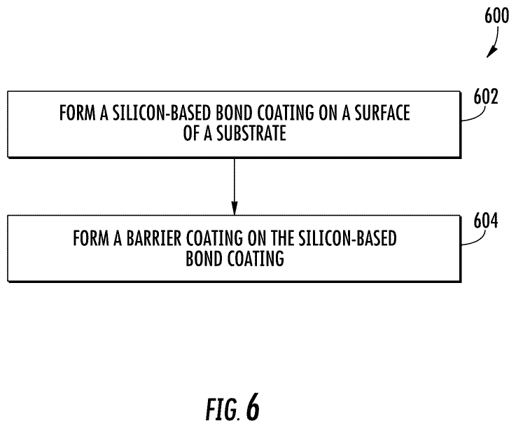

Methods are also generally provided for coating a ceramic component. For example, FIG. 6 shows a diagram of an exemplary method 600 of forming a coating system on a surface of a substrate. At 602, a silicon-based bond coating is formed on the surface of the substrate to include an amorphous silicon phase having grains of crystalline silicon distributed therein, such as described above with respect to silicon-based bond coating 104. As described above, the silicon-based bond coating is formed, in one embodiment, via chemical vapor deposition at a relatively low temperature (e.g., less than 1000° C.) followed by heat treatment at a higher temperature (e.g., greater than 1000° C.). At 604, an environmental barrier coating (EBC) is formed on the silicon-based bond coating.

This written description uses exemplary embodiments to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method of forming a coated component, the method comprising:
forming a silicon-based bond coating on a surface of a substrate, wherein the silicon-based bond coating comprises amorphous silicon phase having grains of crystalline silicon distributed therein; and
forming a barrier coating on the silicon-based bond coating.

2. The method of claim 1, wherein forming the silicon-based bond coating on the surface of the substrate comprises:
chemical vapor depositing a silicon-containing precursor at a deposition temperature that prevents crystallization of a silicon material formed from the silicon-containing precursor during the deposition of the silicon-based bond coating; and
heat treating the silicon-based bond coating at a treatment temperature that is higher than the deposition temperature so as to form the grains of crystalline silicon distributed within the amorphous silicon phase.

3. The method of claim 2, wherein the deposition temperature is 300° C. to 700° C.

4. The method of claim 2, wherein the deposition temperature is 700° C. to 1000° C.

5. The method of claim 2, wherein the treatment temperature is 1000° C. to 1400° C.

6. The method of claim 2, wherein the treatment temperature is ° C. to 1350° C.

7. The method of claim 2, wherein the silicon-containing precursor comprises a silane having a formula SiₙH₂ₙ₊₂ with n being an integer from 2-12.

8. The method of claim 2, wherein the silicon-containing precursor comprises a chlorosilane.

9. The method of claim 2, wherein the chemical vapor depositing of the silicon-containing precursor at the deposition temperature is achieved at a deposition pressure of 9 Torr to 760 Torr.

10. The method of claim 2, wherein the silicon-containing precursor has a precursor flow rate of 0.1 grams per minute (g/m) to 2 g/m during the chemical vapor depositing of the silicon-containing precursor at the deposition temperature.

11. The method of claim 1, wherein the amorphous silicon phase forms a 3-dimensional network that spans a thickness of the silicon-based bond coating and is bonded to the surface of the substrate and to an inner surface of the barrier coating.

12. The method of claim 1, wherein the amorphous silicon phase comprises pure silicon metal.

13. The method of claim 1, wherein the amorphous silicon phase comprises silicon metal with boron, oxygen, nitrogen, or a mixture thereof dispersed therein.

14. The method of claim 1, wherein the grains of crystalline silicon form 0.1% to 99% by volume of the silicon-based bond coating.

15. The method of claim 1, wherein the grains of crystalline silicon form 1% to 65% by volume of the silicon-based bond coating.

16. The method of claim 1, and wherein the grains of crystalline silicon form 1% to 40% by volume of the silicon-based bond coating.

17. The method of claim 1, wherein the grains of the crystalline silicon have an average size of 0.03 μm to 3 μm.

18. The method of claim 1, wherein the amorphous silicon phase is a continuous phase, and wherein the grains of crystalline silicon form a plurality of discrete particulate phases within the amorphous silicon phase.

19. The method of claim 1, wherein the silicon-based bond coating has a thickness that is 25 μm to 275 μm.

20. The method of claim 1, wherein the substrate comprises a ceramic matrix composite (CMC) comprising silicon carbide, silicon nitride, or a combination thereof, and wherein the substrate comprises a plurality of CMC plies.
